(19) United States
(12) Patent Application Publication
(10) Pub. No.: US 2026/0136537 A1
(43) Pub. Date: May 14, 2026

(54) SEMICONDUCTOR DEVICE INCLUDING WORD LINES

(71) Applicant: Samsung Electronics Co., Ltd., Suwon-si (KR)

(72) Inventors: Gyunghyun Yoon, Suwon-si (KR); Youngwoo Kim, Suwon-si (KR)

(21) Appl. No.: 19/380,773

(22) Filed: Nov. 5, 2025

(30) Foreign Application Priority Data
Nov. 8, 2024 (KR) 10-2024-0158291

(51) Int. Cl. H10B 12/00

(52) U.S. Cl. CPC H10B 12/34; H10B 12/09; H10B 12/50

(57) ABSTRACT

A semiconductor device includes a substrate including a plurality of active regions and a plurality of word lines arranged in word line trenches extending in a first horizontal direction in the substrate to intersect the plurality of active regions. Each of the plurality of word lines includes a main portion extending in the first horizontal direction and a first end and a second end arranged at both sides of the main portion. A first word line includes a first conductive line, and a top surface of the first conductive line is at a first vertical level at the first end. A second word line arranged adjacent to the first word line includes a second conductive line, and a top surface of the second conductive line at the first end is at a second vertical level lower than the first vertical level.

### CROSS-REFERENCE TO RELATED APPLICATION

This application is based on and claims priority under 35 U.S.C. § 119 to Korean Patent Application No. 10-2024-0158291, filed on Nov. 8, 2024, in the Korean Intellectual Property Office, the disclosure of which is incorporated by reference herein in its entirety.

### BACKGROUND

The inventive concept relates to a semiconductor device including word lines, and more particularly, to a semiconductor device including word lines of a buried channel array transistor.

As semiconductor devices are downscaled, the sizes of individual microcircuit patterns for implementing semiconductor devices are further reduced. In a semiconductor device having a buried channel array transistor in which a word line is buried in a substrate, there is a problem that, as the width and spacing of the word line decrease, a disconnection defect in the word line or a bridging defect in a word line contact occurs.

### SUMMARY

The inventive concept relates to a semiconductor device with improved reliability capable of preventing a disconnection defect in a word line or a bridging defect in a word line contact.

According to an aspect of the inventive concept, there is provided a semiconductor device including a substrate including a plurality of active regions and a plurality of word lines arranged in a plurality of word line trenches extending in a first horizontal direction in the substrate and arranged to intersect the plurality of active regions. Each of the plurality of word lines includes a main portion extending in the first horizontal direction and a first end and a second end arranged at both sides of the main portion. A first word line among the plurality of word lines includes a first conductive line, and a top surface of the first conductive line is at a first vertical level at the first end. A second word line arranged adjacent to the first word line among the plurality of word lines includes a second conductive line, and a top surface of the second conductive line at the first end is at a second vertical level lower than the first vertical level.

According to another aspect of the inventive concept, there is provided a semiconductor device including a substrate including a cell array region with a plurality of active regions defined, a peripheral circuit region with at least one peripheral circuit active region defined, and an interface region having an interface trench between the cell array region and the peripheral circuit region, an insulating boundary structure in the interface trench and surrounding the plurality of active regions in a plan view, and a plurality of word lines extending in a first horizontal direction across the plurality of active regions in the cell array region and extending into the insulating boundary structure of the interface region, the plurality of word lines including a main portion vertically overlapping the cell array region, a first end vertically overlapping the interface region arranged on one side of the cell array region, and a second end vertically overlapping the interface region on an opposite side of the first end. A first word line among the plurality of word lines includes a first conductive line including an extension arranged at the main portion and the second end, and a landing portion arranged at the first end and integrally connected to the extension and having a top surface at a vertical level higher than a top surface of the extension, a first upper conductive line arranged on the extension, a first capping layer arranged on a top surface of the first upper conductive line and a top surface of the landing portion, and a first word line contact arranged on the landing portion of the first conductive line.

According to another aspect of the inventive concept, there is provided a semiconductor device including a substrate including a cell array region with a plurality of active regions defined, a peripheral circuit region with at least one peripheral circuit active region defined, and an interface region having an interface trench between the cell array region and the peripheral circuit region, an insulating boundary structure in the interface trench and surrounding the plurality of active regions in a plan view, a plurality of word lines extending in a first horizontal direction across the plurality of active regions in the cell array region and extending into the insulating boundary structure of the interface region, the plurality of word lines including a main portion vertically overlapping the cell array region, a first end vertically overlapping the interface region arranged on one side of the cell array region, and a second end vertically overlapping the interface region on an opposite side of the first end. A first word line among the plurality of word lines includes a first conductive line including an extension arranged at the main portion and the second end, and a landing portion arranged at the first end and integrally connected to the extension and having a top surface at a vertical level higher than a top surface of the extension and a first upper conductive line arranged on the extension of the first conductive line. Among the plurality of word lines, a second word line adjacent to the first word line includes a second conductive line including an extension arranged at the main portion and the second end, and a landing portion arranged at the first end and integrally connected to the extension and having a top surface at a vertical level higher than a top surface of the extension of the second conductive line and a second upper conductive line arranged on the extension of the second conductive line.

### BRIEF DESCRIPTION OF THE DRAWINGS

Embodiments will be more clearly understood from the following detailed description taken in conjunction with the accompanying drawings in which:

FIG. 1 is a layout diagram illustrating a semiconductor device according to example embodiments;

FIG. 2 is an enlarged layout diagram of a portion "EX1" of FIG. 1;

FIG. 3 is a cross-sectional view taken along the line B1-B1' of FIG. 2;

FIG. 4 is a cross-sectional view taken along the line B2-B2' of FIG. 2;

FIG. 5 is a cross-sectional view taken along the line B3-B3' of FIG. 2;

FIG. 6 is an enlarged cross-sectional view of a portion "EX2" of FIG. 3;

FIGS. 7 to 9 are cross-sectional views illustrating a semiconductor device according to example embodiments;

FIG. 10 is an enlarged diagram of a portion "EX2" of FIG. 7; and

FIGS. 11, 12, 13A, 13B, 14A, 14B, 14C, 15, 16A, 16B, 16C, 17A, 17B, 17C, 18A, 18B, 18C, 19A, 19B, 19C, 20A, 20B, and 20C are schematic diagrams illustrating a method of manufacturing a semiconductor device according to example embodiments.

### DETAILED DESCRIPTION OF THE EMBODIMENTS

Hereinafter, embodiments of the inventive concept will be described in detail with reference to the accompanying drawings. Like reference characters refer to like elements throughout.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

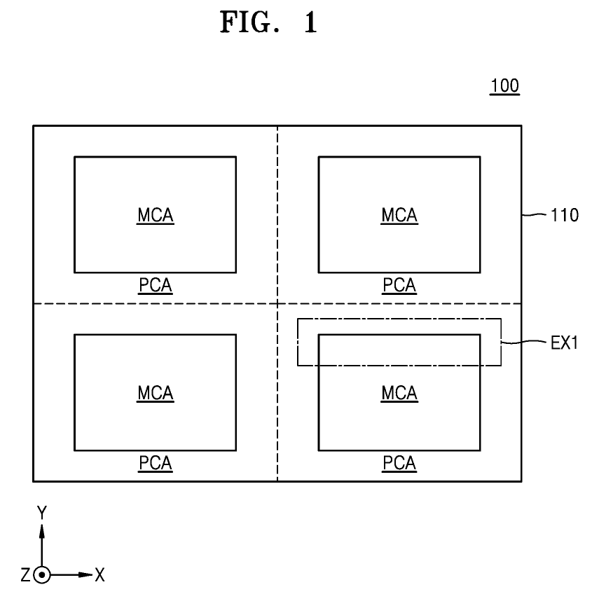

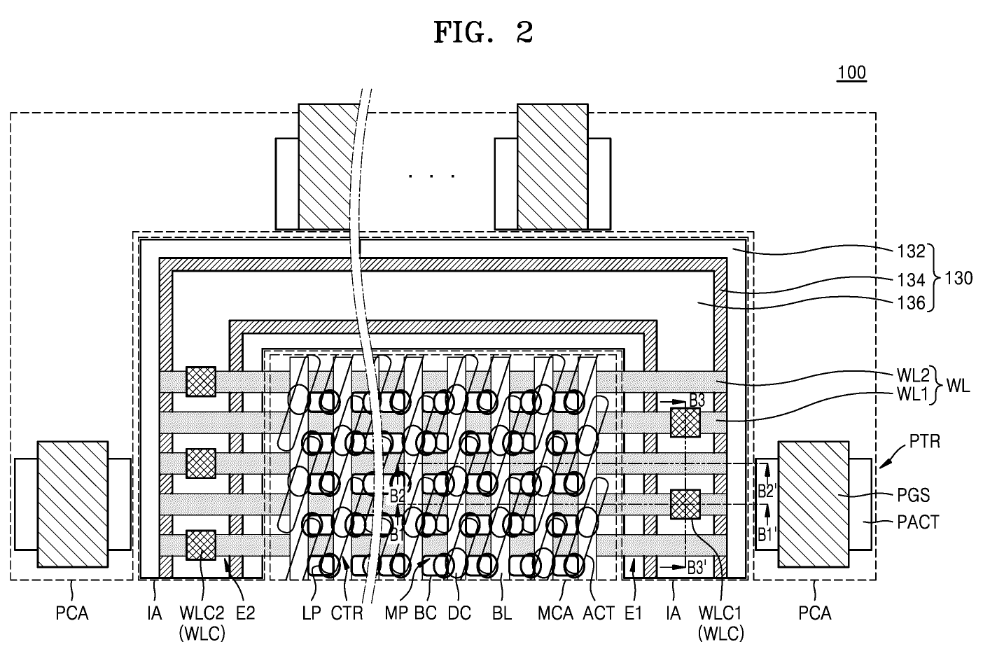

FIG. 1 is a layout diagram illustrating a semiconductor device 100 according to example embodiments. FIG. 2 is an enlarged layout diagram of a portion "EX1" of FIG. 1.

Referring to FIGS. 1 and 2, the semiconductor device 100 may include a substrate 110 including a cell array region MCA and a peripheral circuit region PCA. The substrate 110 may further include an interface region IA between the cell array region MCA and the peripheral circuit region PCA.

In embodiments, the cell array region MCA may include a memory cell region of a dynamic random access memory (DRAM) device, and the peripheral circuit region PCA may include a core region or a peripheral circuit region of the DRAM device. For example, the cell array region MCA may include a cell transistor CTR and a capacitor structure connected thereto, and the peripheral circuit region PCA may include a peripheral circuit transistor PTR for transmitting signals and/or power to the cell transistor CTR included in the cell array region MCA. In embodiments, the peripheral circuit transistor PTR may constitute various circuits such as a command decoder, control logic, an address buffer, a row decoder, a column decoder, a sense amplifier, and a data input/output circuit.

According to embodiments, the interface region IA may include an insulating boundary structure 130 configured to electrically insulate the cell array region MCA from the peripheral circuit region PCA. For example, the insulating boundary structure 130 may have a closed loop shape surrounding a plurality of active regions ACT in a plan view. The insulating boundary structure 130 may include a first insulating liner 132, a second insulating liner 134, and a buried insulating layer 136.

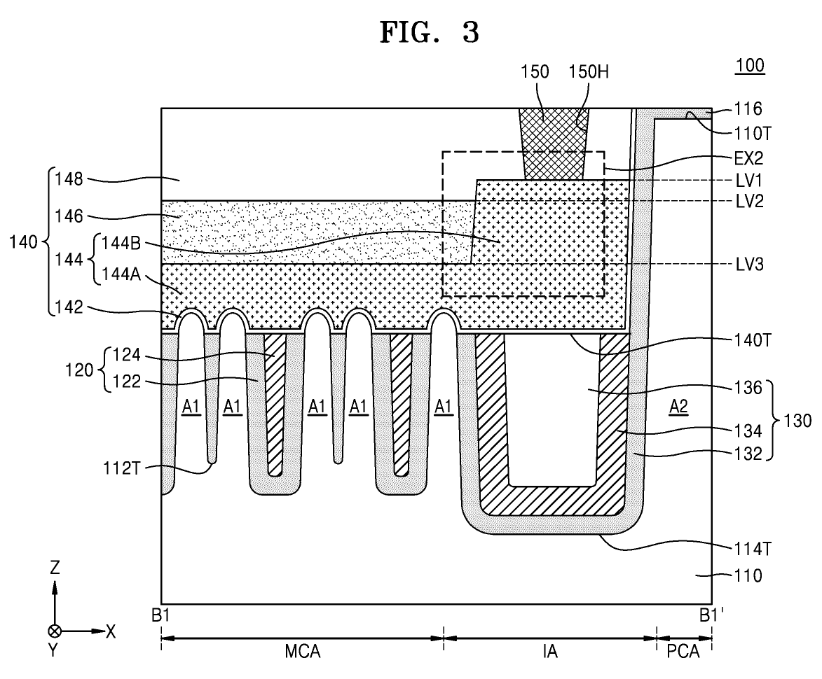

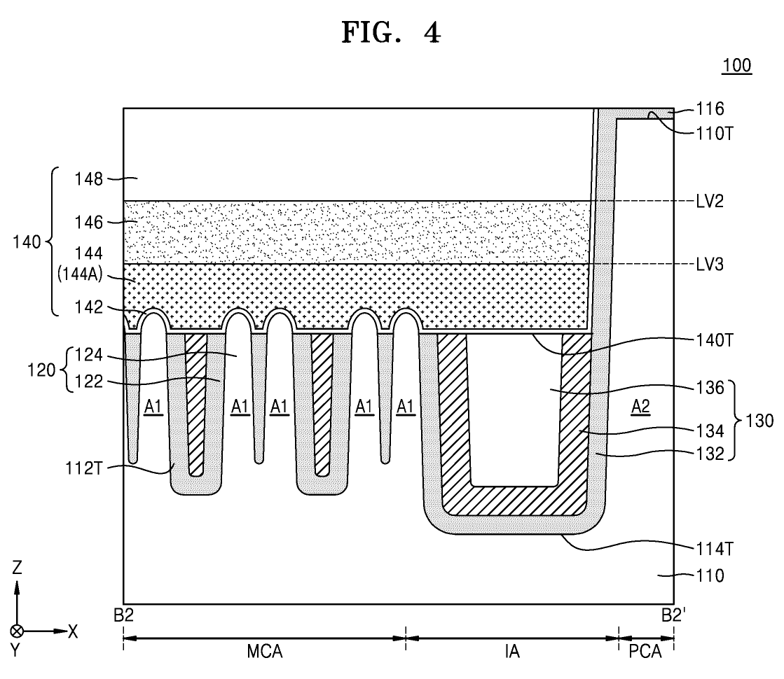

According to embodiments, the substrate 110 may include the plurality of active regions ACT. According to embodiments, the plurality of active regions ACT of the cell array region MCA may be defined by a device isolation structure 120 (refer to FIG. 3). At least one peripheral circuit active region PACT may be defined in the peripheral circuit region PCA. The plurality of active regions ACT of the cell array region MCA may be spaced apart from the peripheral circuit active region PACT of the peripheral circuit region PCA with the insulating boundary structure 130 therebetween. The peripheral circuit transistor PTR may include the peripheral circuit active region PACT, a peripheral circuit gate electrode PGS, and a peripheral circuit gate dielectric layer between the peripheral circuit active region PACT and the peripheral circuit gate electrode PGS.

According to embodiments, in the cell array region MCA, each of the plurality of active regions ACT may be arranged to have a long axis extending in a diagonal direction with respect to a first horizontal direction X and a second horizontal direction Y intersecting the first horizontal direction X, where the first and second horizontal directions X and Y are perpendicular to each other. According to embodiments, the plurality of active regions ACT may be spaced apart from one another in the first or second horizontal direction X or Y.

According to embodiments, a plurality of word lines WL may extend lengthwise in parallel to one another in the first horizontal direction X across the plurality of active regions ACT. According to embodiments, a plurality of bit lines BL on the plurality of word lines WL may extend lengthwise in parallel to one another in the second horizontal direction Y. The plurality of bit lines BL may be connected to the plurality of active regions ACT through direct contacts DC. Each of the plurality of word lines WL may receive a driving voltage through each of a plurality of word line contacts WLC connected to the plurality of word lines WL in the interface region IA.

The plurality of word lines WL may include a main portion MP arranged on the cell array region MCA, and a first end E1 and a second end E2 connected to both sides of the main portion MP. The first end E1 and the second end E2 may be arranged on the interface region IA, and for example, the second end E2 may be arranged opposite to the first end E1. For example, each of the word lines WL may extend from the interface region IA at one side of the cell array region MCA to the interface region IA at the opposite side of the cell array region MCA. As illustrated in FIG. 2, the plurality of word lines WL may include a plurality of first word lines WL1 and a plurality of second word lines WL2 arranged alternately. In embodiments, a first word line contact WLC1 may be arranged at a first end E1 of each of the plurality of first word lines WL1, and a first word line contact WLC1 may not be arranged at a second end E2 opposite to the first end E1 of each of the plurality of first word lines WL1. In embodiments, a second word line contact WLC2 may be arranged at a second end E2 of each of the plurality of second word lines WL2, and a second word line contact WLC2 may not be arranged at a first end E1 of each of the plurality of second word lines WL2.

In embodiments, each of the first and second word line contacts WLC1 and WLC2 may have a width (for example, a width in the second horizontal direction Y) greater than that of each of the first and second word lines WL1 and WL2.

According to embodiments, a plurality of buried contacts BC may be arranged between two adjacent bit lines BL among the plurality of bit lines BL. According to embodiments, the plurality of buried contacts BC may be arranged in a matrix in the first horizontal direction X and the second horizontal direction Y. According to embodiments, a plurality of landing pads LP may be arranged on the plurality of buried contacts BC, respectively. According to embodiments, the plurality of landing pads LP may at least partially overlap the plurality of buried contacts BC in a vertical direction Z, respectively. According to embodiments, the plurality of buried contacts BC and the plurality of landing pads LP may connect lower electrodes of capacitors formed on the plurality of bit lines BL to the plurality of active regions ACT.

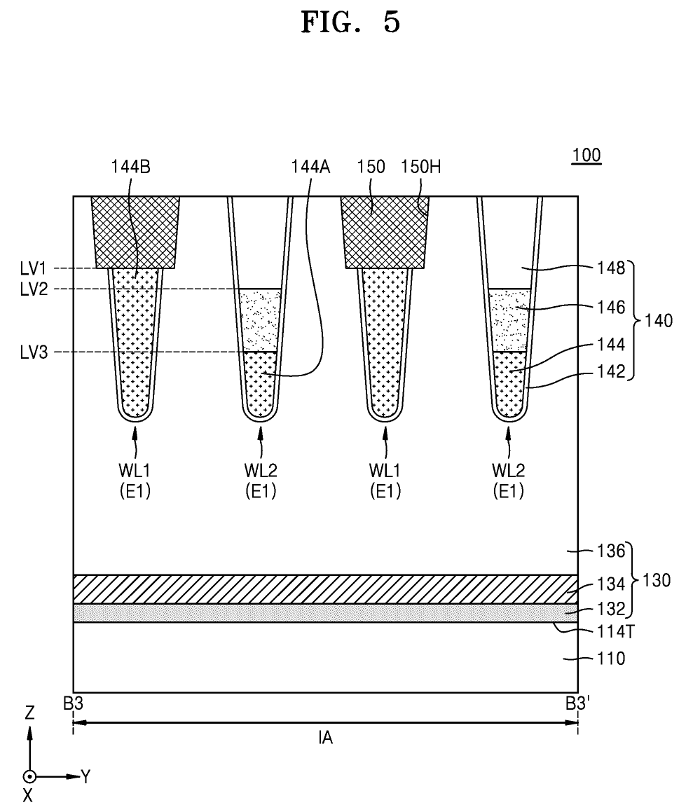

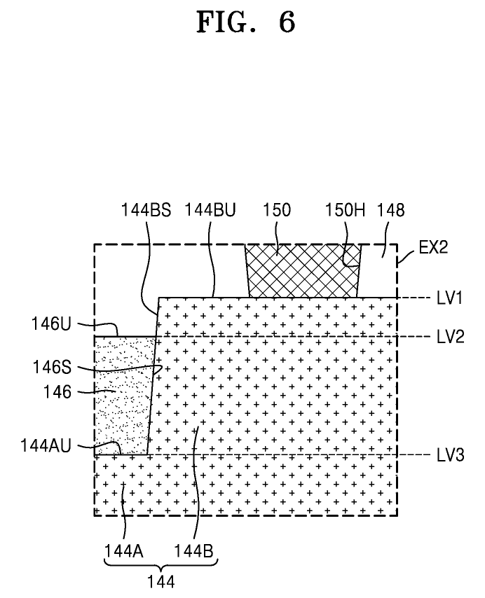

FIGS. 3 to 6 are cross-sectional views illustrating main components of the semiconductor device 100 according to an example embodiment. Specifically, FIG. 3 is a cross-sectional view taken along the line B1-B1' of FIG. 2. FIG. 4 is a cross-sectional view taken along the line B2-B2' of FIG. 2. FIG. 5 is a cross-sectional view taken along the line B3-B3' of FIG. 2. FIG. 6 is an enlarged cross-sectional view of a portion "EX2" of FIG. 3. In FIGS. 3-6, illustrations of the direct contact DC, the bit line BL, the buried contact BC, and the landing pad LP described with reference to FIG. 2 are omitted.

Referring to FIGS. 3 to 6 together with FIG. 2, the semiconductor device 100 may include a substrate 110 including a plurality of active regions A1 defined in the cell array region MCA and a peripheral circuit active region A2 defined in the peripheral circuit region PCA. According to embodiments, the plurality of active regions A1 and the peripheral circuit active region A2 may be defined by a device isolation trench 112T and an interface trench 114T. The device isolation trench 112T may be filled with the device isolation structure 120, and the interface trench 114T may be filled with the insulating boundary structure 130. The plurality of active regions A1 may correspond to the plurality of active regions ACT described with reference to FIG. 2, and may hereinafter be referred to as cell active regions. The peripheral circuit active region A2 may correspond to the peripheral circuit active region PACT described with reference to FIG. 2.

The substrate 110 may include silicon (Si), for example, single crystalline Si, polycrystalline Si, or amorphous Si. In other embodiments, the substrate 110 may include at least one selected from germanium (Ge), silicon germanium (SiGe), silicon carbide (SiC), gallium arsenide (GaAs), indium arsenide (InAs), and indium phosphide (InP). In some embodiments, the substrate 110 may include a conductive region, for example, a well doped with impurities or a structure doped with impurities.

In the cell array region MCA, the device isolation structure 120 may include a first insulating layer 122 and a second insulating layer 124. Part of the device isolation structure 120 may have a structure in which the first insulating layer 122 and the second insulating layer 124 are sequentially stacked. In example embodiments, in a region below the gate structures 140, upper surfaces of the first insulating layer 122 and the second insulating layer 124 may be at the same vertical level (e.g., level in the vertical direction Z). A first region of the device isolation trench 112T having a relatively small width in the first and/or second horizontal direction X and/or Y may be filled with only the first insulating layer 122, and a second region of the device isolation trench 112T having a relatively large width in the first and/or second horizontal direction X and/or Y may be filled with the first insulating layer 122 and the second insulating layer 124. For example, in the second region, the first insulating layer 122 may cover a bottom surface and an internal wall of the device isolation trench 112T and may fill part of the device isolation trench 112T, and the second insulating layer 124 may fill the remaining space of the device isolation trench 112T on the first insulating layer 122.

In the interface region IA, the insulating boundary structure 130 may include a first insulating liner 132 and a second insulating liner 134 sequentially stacked on a bottom surface and an internal wall of the interface trench 114T, and a buried insulating layer 136 filling the interface trench 114T on the second insulating liner 134. In example embodiments, in a region below the gate structures 140, upper surfaces of the first insulating liner 132, the second insulating liner 134, and the buried insulating layer 136 may be at the same vertical level (e.g., level in the vertical direction Z).

In some embodiments, each of the first insulating layer 122, the first insulating liner 132, and the buried insulating layer 136 may include an oxide layer, and each of the second insulating layer 124 and the second insulating liner 134 may include a nitride layer. In some embodiments, the oxide layer constituting the first insulating layer 122 and the first insulating liner 132 may include a silicon oxide layer formed by an atomic layer deposition (ALD) process. In some embodiments, each of the second insulating layer 124 and the second insulating liner 134 may include a silicon nitride layer. In some embodiments, the silicon oxide layer constituting the buried insulating layer 136 may include tonen silazene (TOSZ), a high density plasma (HDP) oxide layer, or an undoped silicate glass (USG) oxide layer. In other embodiments, the oxide layer constituting the buried insulating layer 136 may include a spin-on-glass (SOG) oxide layer including silicate, siloxane, methyl silsesquioxane (MSQ), hydrogen silsesquioxane (HSQ), polysilazane, or a combination thereof. However, the inventive concept is not limited thereto.

In some embodiments, the semiconductor device 100 may include an insulating thin film 116 covering a top surface 110T of the substrate 110. In some embodiments, the insulating thin film 116 may include the same material as an insulating material constituting the first insulating liner 132. However, the inventive concept is not limited thereto.

According to embodiments, in the cell array region MCA, a plurality of word line trenches 140T may be formed to extend in the first horizontal direction X across the plurality of active regions A1 and the device isolation structure 120. According to embodiments, each of the plurality of word line trenches 140T may include a portion extending into the interface region IA. For example, in the interface region IA, each of the plurality of word line trenches 140T may cross part of the insulating boundary structure 130. The plurality of word line trenches 140T may have a plurality of line shapes extending parallel to one another in the first horizontal direction X.

According to embodiments, the plurality of word line trenches 140T may be individually filled with a plurality of gate structures 140. According to embodiments, the plurality of gate structures 140 may extend lengthwise in the first horizontal direction X, and may be spaced apart from one another in the second horizontal direction Y. According to embodiments, the plurality of gate structures 140 may extend across the plurality of active regions A1 and the device isolation structure 120 in the cell array region MCA, and both ends of the plurality of gate structures 140 in the first horizontal direction X may partially extend into the interface region IA, and may partially extend into the insulating boundary structure 130. In some embodiments, the plurality of gate structures 140 may be spaced apart from the peripheral circuit active region A2 with part of the insulating boundary structure 130 therebetween. The plurality of gate structures 140 may correspond to the plurality of word lines WL described with reference to FIG. 2. According to embodiments, each of the plurality of gate structures 140 may include a gate dielectric layer 142, a conductive line 144, an upper conductive line 146, and a capping layer 148.

According to embodiments, a vertical level of a portion of a bottom surface of the word line trench 140T in which the active region A1 of the substrate 110 is exposed may be higher than a vertical level of a portion of a bottom surface of the word line trench 140T in which the device isolation structure 120 and the insulating boundary structure 130 are exposed. For example, in a region in which the plurality of active regions A1 overlap the gate structure 140 in the vertical direction Z, the plurality of active regions A1 may include a saddle fin portion at a higher vertical level than the device isolation structure 120 and the insulating boundary structure 130. The saddle fin portion of the plurality of active regions A1 may be covered with the conductive line 144, and a saddle fin field effect transistor (FET) may be formed in the plurality of active regions A1.

According to embodiments, the gate dielectric layer 142 may conformally cover the bottom surface and an internal wall of the word line trench 140T. For example, the gate dielectric layer 142 may have a shape corresponding to a bottom surface and internal wall profile of the word line trench 140T. For example, the gate dielectric layer 142 may include a portion in contact with the saddle fin portion of the plurality of active regions A1, a portion in contact with the device isolation structure 120, and a portion in contact with the insulating boundary structure 130.

In some embodiments, the gate dielectric layer 142 may include a silicon oxide layer, a silicon nitride layer, a silicon oxynitride layer, an oxide/nitride/oxide (ONO) layer, or a high-k dielectric layer having a higher dielectric constant than the silicon oxide layer.

In embodiments, the conductive line 144 may extend in the first horizontal direction X by filling part of the word line trench 140T on the gate dielectric layer 142. The conductive line 144 may contact an upper surface of the gate dielectric layer 142. In some embodiments, a bottom surface of the conductive line 144 may have a concavo-convex shape corresponding to a bottom surface profile of the word line trench 140T. In some embodiments, the saddle fin portion of the plurality of active regions A1 may be spaced apart from the conductive line 144 with the gate dielectric layer 142 therebetween.

In embodiments, the conductive line 144 may include an extension 144A vertically overlapping the plurality of active regions A1 in the cell array region MCA and a landing portion 144B vertically overlapping the insulating boundary structure 130 in the interface region IA. The landing portion 144B may extend from an end of the extension 144A in the first horizontal direction X.

In embodiments, as described above with reference to FIG. 2, the plurality of word lines WL may include the main portion MP arranged at a position vertically overlapping the cell array region MCA, and may include the first end E1 and the second end E2 at positions vertically overlapping the interface region IA. The first end E1 and the second end E2 of the plurality of word lines WL may indicate parts of the plurality of word lines WL of which sidewalls are covered with the insulating boundary structure 130 at positions vertically overlapping the interface region IA.

In embodiments, as described above with reference to FIG. 2, the plurality of word lines WL may include the first word lines WL1 and the second word lines WL2 arranged alternately, the conductive line 144 corresponding to the first word line WL1 may have the landing portion 144B at the first end E1, and the conductive line 144 corresponding to the second word line WL2 may have the landing portion 144B at the second end E2 opposite to the first end E1. In FIGS. 3 to 5, only the first end E1 of the conductive line 144 corresponding to the first word line WL1 and the first end E1 of the second word line WL2 are illustrated. The landing portion 144B may be arranged at the first end E1 of the first word line WL1 and the landing portion 144B may not be arranged at the first end E1 of the second word line WL2.

In some embodiments, a top surface 144BU of the landing portion 144B may be at a vertical level higher than a top surface 144AU of the extension 144A. In some embodiments, the top surface 144BU of the landing portion 144B may be at a first vertical level LV1, and the top surface 144AU of the extension 144A may be at a third vertical level LV3 lower than the first vertical level LV1. For example, the top surface 144BU of the landing portion 144B may be arranged closer to the top surface 110T of the substrate 110 than the top surface 144AU of the extension 144A. In some embodiments, a first height, which is a length of the extension 144A in the vertical direction Z, may be less than a second height, which is a length of the landing portion 144B in the vertical direction Z. For example, the conductive line 144 may have a step structure at a point at which the extension 144A and the landing portion 144B meet.

In some embodiments, the top surface 144AU of the extension 144A may extend relatively flatly. For example, the top surface 144AU of the extension 144A may extend linearly in a vertical cross-section. In some embodiments, a bottom surface of the extension 144A may have a concavo-convex shape corresponding to the bottom surface profile of the word line trench 140T.

In some embodiments, the landing portion 144B may have a first sidewall 144BS facing the cell array region MCA at a vertical level higher than the extension 144A and a second sidewall opposite to the first sidewall 144BS in the first horizontal direction X. In some embodiments, the second sidewall may face the peripheral circuit active region A2 with part of the insulating boundary structure 130 therebetween. In some embodiments, the first sidewall 144BS of the landing portion 144B may meet the top surface 144AU of the extension 144A.

In some embodiments, the conductive line 144 may include a metal material, conductive metal nitride, or a combination thereof. In some embodiments, the conductive line 144 may include copper (Cu), tungsten (W), cobalt (Co), ruthenium (Ru), manganese (Mn), titanium (Ti), tantalum (Ta), aluminum (Al), molybdenum (Mo), La, LaO, TiN, TaN, WN, TiSiN, WSiN, or a combination thereof.

In some embodiments, the conductive line 144 may include a metal-containing liner (not shown) and a conductive core (not shown) sequentially stacked on the gate dielectric layer 142. In this case, the metal-containing liner may have a shape corresponding to the bottom surface profile of the word line trench 140T and may be arranged on the gate dielectric layer 142. The conductive core may fill part of the word line trench 140T on the metal-containing liner. A bottom surface of the conductive core may have a concavo-convex shape corresponding to the bottom surface profile of the word line trench 140T, and a top surface of the conductive core may extend relatively flatly. In some embodiments, the metal-containing liner may include Ti, Ta, W, TiN, TaN, WN, WCN, TiSiN, TaSiN, WSiN, or a combination thereof, and the conductive core may include Mo, Cu, W, Co, Ru, Mn, Ti, Ta, Al, a combination thereof, or an alloy thereof. However, the inventive concept is not limited thereto.

In embodiments, the upper conductive line 146 may be arranged on the extension 144A of the conductive line 144. According to embodiments, the upper conductive line 146 may be arranged on the entire top surface 144AU of the extension 144A of the conductive line 144 and may extend in the first horizontal direction X.

According to embodiments, the upper conductive line 146 may vertically overlap the extension 144A. According to embodiments, a sidewall 146S of the upper conductive line 146 may be in contact with the first sidewall 144BS of the landing portion 144B of the conductive line 144. In some embodiments, the upper conductive line 146 may not be in contact with the top surface 144BU of the landing portion 144B and may not vertically overlap the top surface 144BU of the landing portion 144B. In some embodiments, a top surface 146U of the upper conductive line 146 may be at a second vertical level LV2 lower than the top surface 144BU of the landing portion 144B.

In some embodiments, the upper conductive line 146 may include polysilicon or doped polysilicon. For example, the upper conductive line 146 may assist the electrical connection of the cell transistor CTR (refer to FIG. 2) to the conductive line 144.

According to embodiments, the capping layer 148 may be arranged on the conductive line 144 and the upper conductive line 146, and may fill the remaining space of the word line trench 140T. In some embodiments, a bottom surface of the capping layer 148 may be in contact with the top surface 144BU of the landing portion 144B and the top surface 146U of the upper conductive line 146. A sidewall of the capping layer 148 in the first horizontal direction X may be in contact with the gate dielectric layer 142, and may face the peripheral circuit active region A2 with part of the gate dielectric layer 142 and the insulating boundary structure 130 therebetween.

In some embodiments, the capping layer 148 may include a silicon oxide layer, a silicon nitride layer, a silicon oxynitride layer, or a combination thereof.

According to embodiments, a plurality of conductive contacts 150 respectively connected to the plurality of gate structures 140 may be arranged in the interface region IA. According to embodiments, the plurality of conductive contacts 150 may be arranged in a plurality of contact holes 150H penetrating the capping layer 148 in the vertical direction Z in the interface region IA, respectively. In some embodiments, the plurality of conductive contacts 150 may be electrically connected to a word line driving circuit (not shown) of the peripheral circuit region PCA. The plurality of conductive contacts 150 may correspond to the plurality of word line contacts WLC described above with reference to FIG. 2.

The plurality of conductive contacts 150 may be in contact with the landing portion 144B of the conductive line 144 through the capping layer 148. A bottom surface of each of the plurality of conductive contacts 150 may be in contact with the top surface 144BU of the landing portion 144B, and a sidewall of each of the plurality of conductive contacts 150 may be in contact with the capping layer 148 and the insulating boundary structure 130. In some embodiments, the plurality of conductive contacts 150 may be spaced apart from the upper conductive line 146.

In embodiments, as illustrated in FIG. 5, each of the plurality of conductive contacts 150 may have a width greater than a width of the conductive line 144 in the second horizontal direction Y or a width of the upper conductive line 146 in the second horizontal direction Y. Both sidewalls of each of the plurality of conductive contacts 150, which are spaced apart from each other in the second horizontal direction Y, may protrude outward with respect to sidewalls of the word line trench 140T.

It is illustrated in FIGS. 3 and 4 that the bottom surfaces of each of the plurality of conductive contacts 150 is at the first vertical level LV1. However, the inventive concept is not limited thereto. For example, some of the plurality of conductive contacts 150 may extend into the landing portion 144B, and in this case, the bottom surface of each of the plurality of conductive contacts 150 may be at a vertical level lower than the first vertical level LV1 and higher than the second vertical level LV2.

In some embodiments, each of the plurality of conductive contacts 150 may include a conductive barrier (not shown) covering an internal wall and a bottom surface of the contact hole 150H and a conductive plug (not shown) filling the contact hole 150H on the conductive barrier. The conductive barrier may include Ti, Ta, W, TiN, TaN, WN, WCN, TiSiN, TaSiN, WSiN, or a combination thereof, and the conductive plug may include Mo, Cu, W, Co, Ru, Mn, Ti, Ta, Al, a combination thereof, or an alloy thereof. However, the inventive concept is not limited thereto.

As illustrated in FIG. 5, the conductive contact 150 arranged on the first end E1 of the first word line WL1 may be arranged on the landing portion 144B of the conductive line 144, and the conductive contact 150 may not be arranged on the first end E1 of the second word line WL2 adjacent to the first end E1 of the first word line WL1. In addition, the upper conductive line 146 may be arranged on the extension 144A of the conductive line 144 at the first end E1 of the second word line WL2, and a level of the top surface of the upper conductive line 146 may be lower than a level of a bottom surface of the conductive contact 150. Therefore, in the process of forming the conductive contact 150 with a relatively large width on the first word line WL1, although the mask pattern is misaligned, a sufficient distance (a distance in the horizontal or vertical direction) from the adjacent second word line WL2 may be secured. Accordingly, a bridging defect in the conductive contact 150 may be prevented.

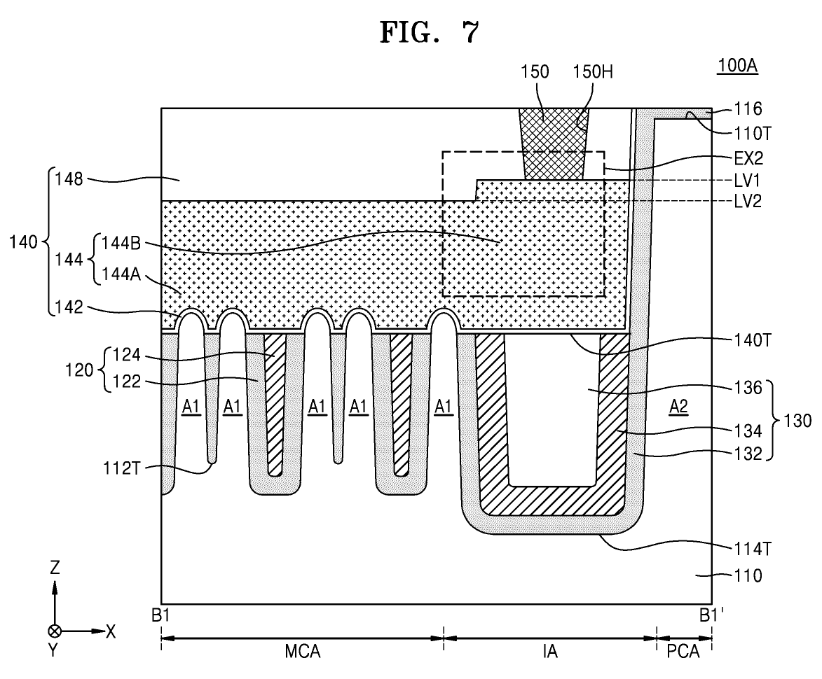

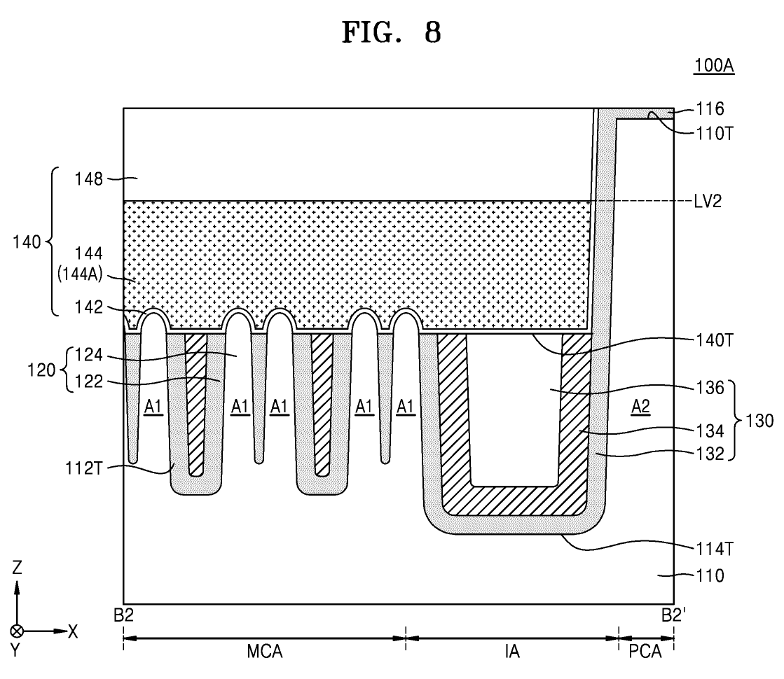

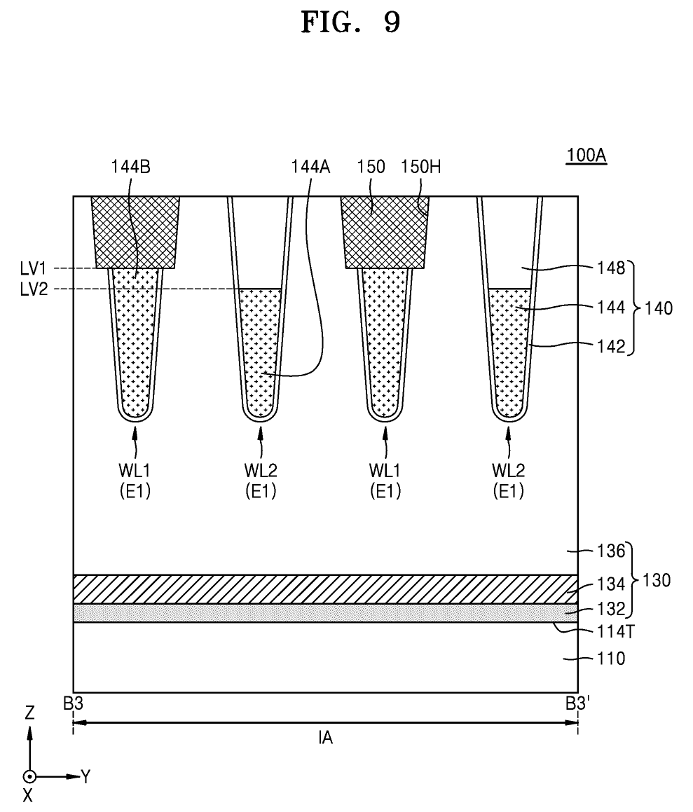

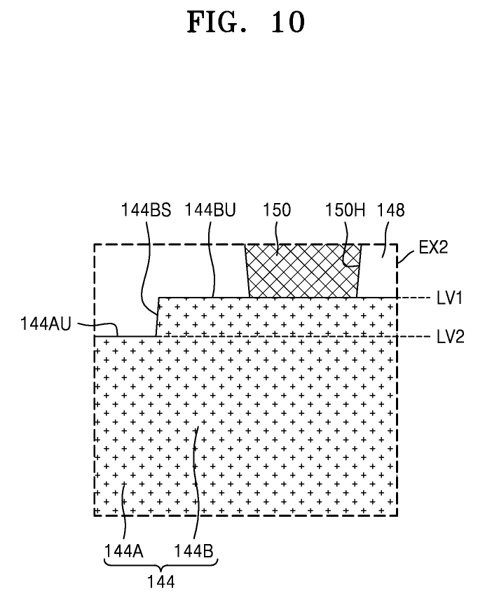

FIGS. 7 to9 are cross-sectional views illustrating a semiconductor device 100A according to example embodiments. Specifically, FIGS. 7 to 9 are cross-sectional views corresponding to the lines B1-B1′, B2-B2′, and B3-B3′ of FIG. 2, respectively. FIG. 10 is an enlarged diagram of a portion "EX2" of FIG. 7.

Because the semiconductor device 100A described with reference to FIGS. 7 to 10 is similar to the semiconductor device 100 described with reference to FIGS. 3 to 6 except that the upper conductive line 146 is omitted, the above-described differences will mainly be described.

Referring to FIGS. 7 to 10, a gate structure 140 may include a gate dielectric layer 142, a conductive line 144, and a capping layer 148 arranged in a word line trench 140T. The conductive line 144 may include an extension 144A and a landing portion 144B, a top surface 144BU of the landing portion 144B may be at a first vertical level LV1, and a top surface 144AU of the extension 144A may be at a second vertical level LV2 lower than the first vertical level LV1.

In embodiments, the capping layer 148 may be in contact with the top surface 144AU of the extension 144A and the top surface 144BU of the landing portion 144B in the word line trench 140T and may extend lengthwise in the first horizontal direction X.

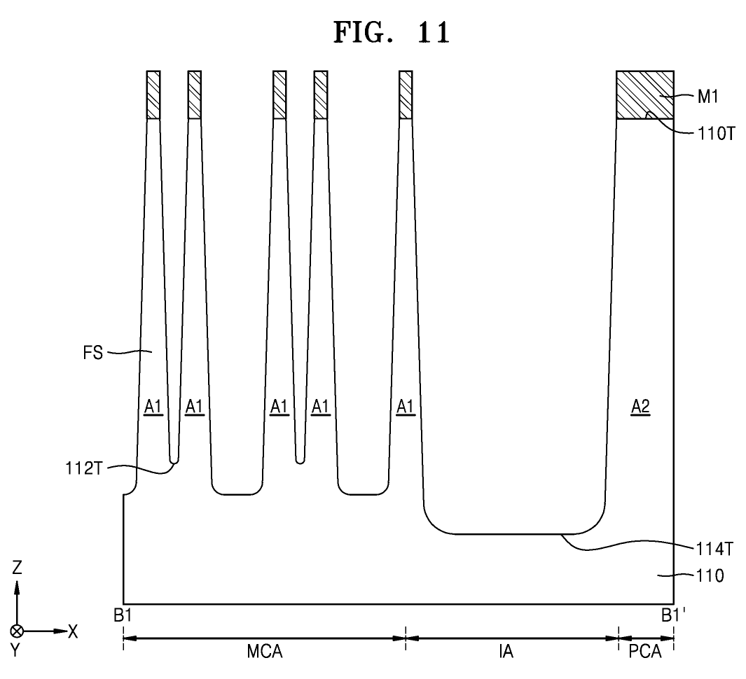

FIGS. 11, 12, 13A, 13B, 14A, 14B, 14C, 15, 16A, 16B, 16C, 17A, 17B, 17C, 18A, 18B, 18C, 19A, 19B, 19C, 20A, 20B, and 20C are schematic diagrams illustrating a method of manufacturing a semiconductor device 100, according to example embodiments.

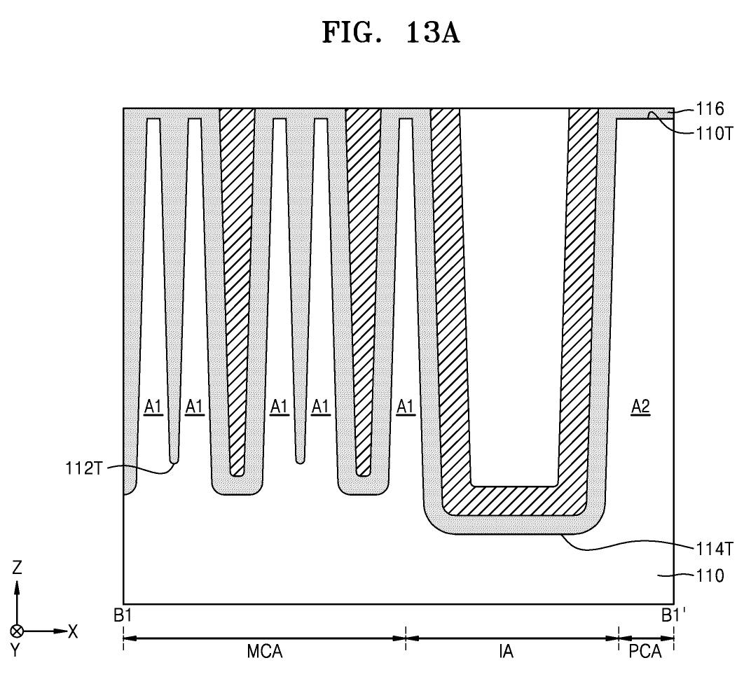

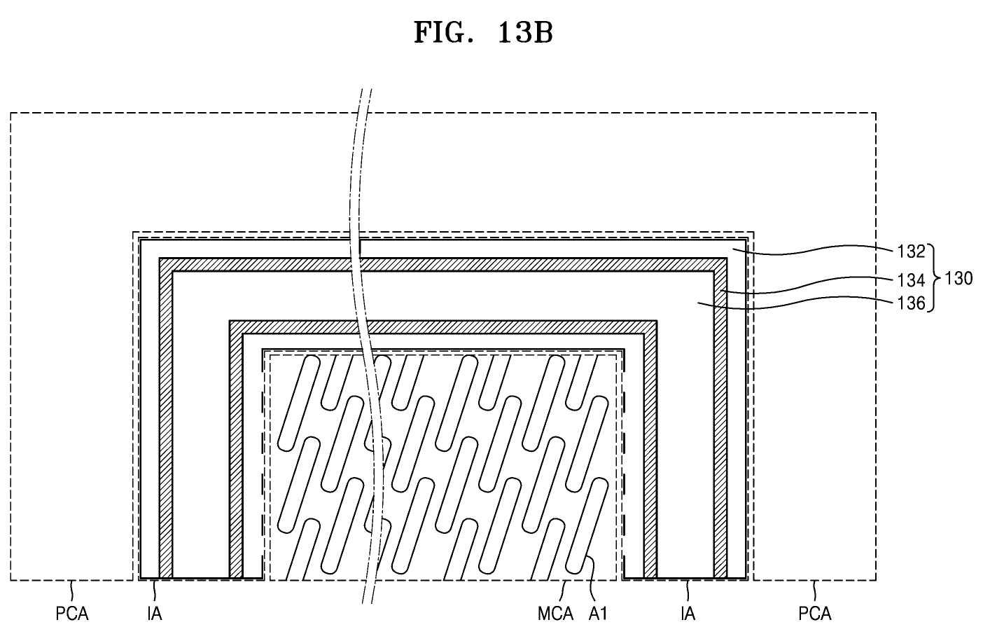

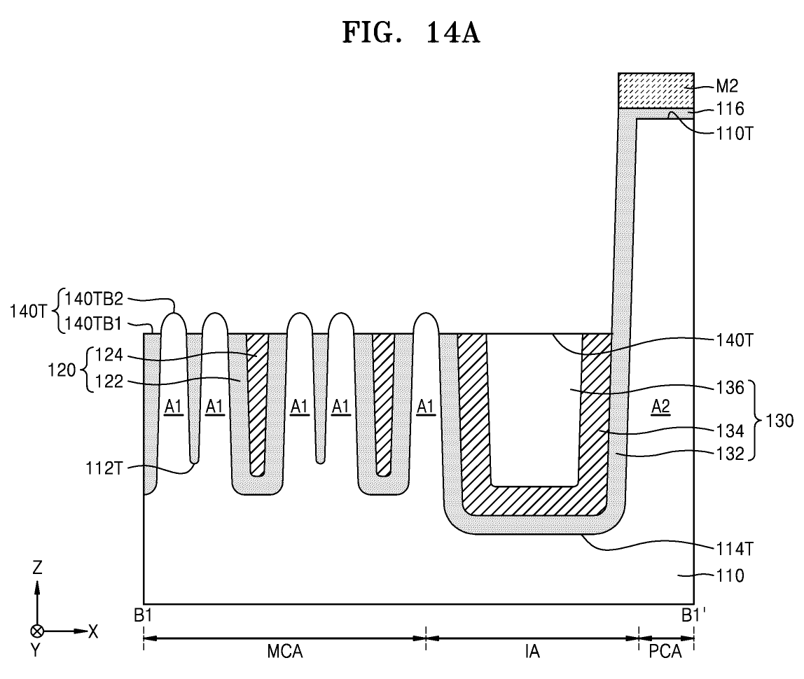

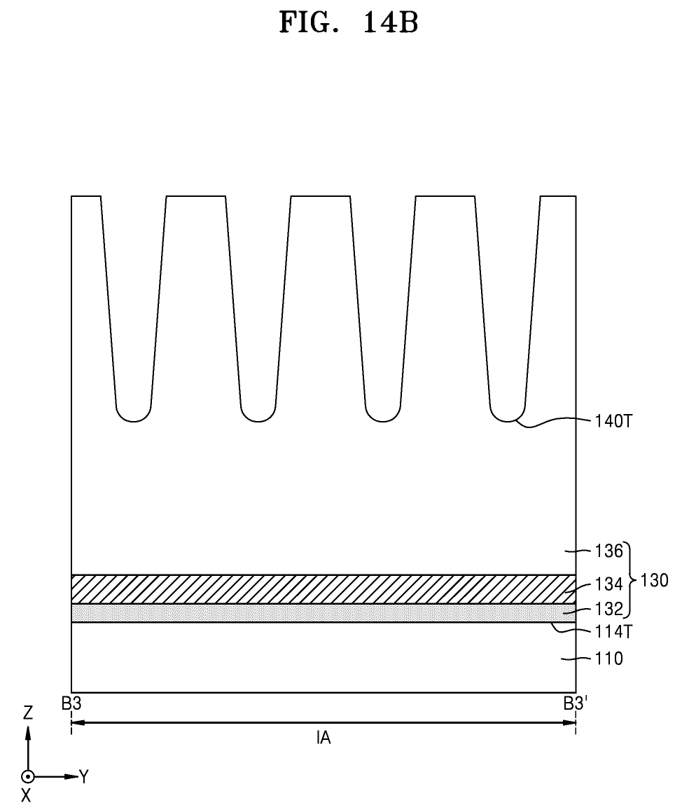

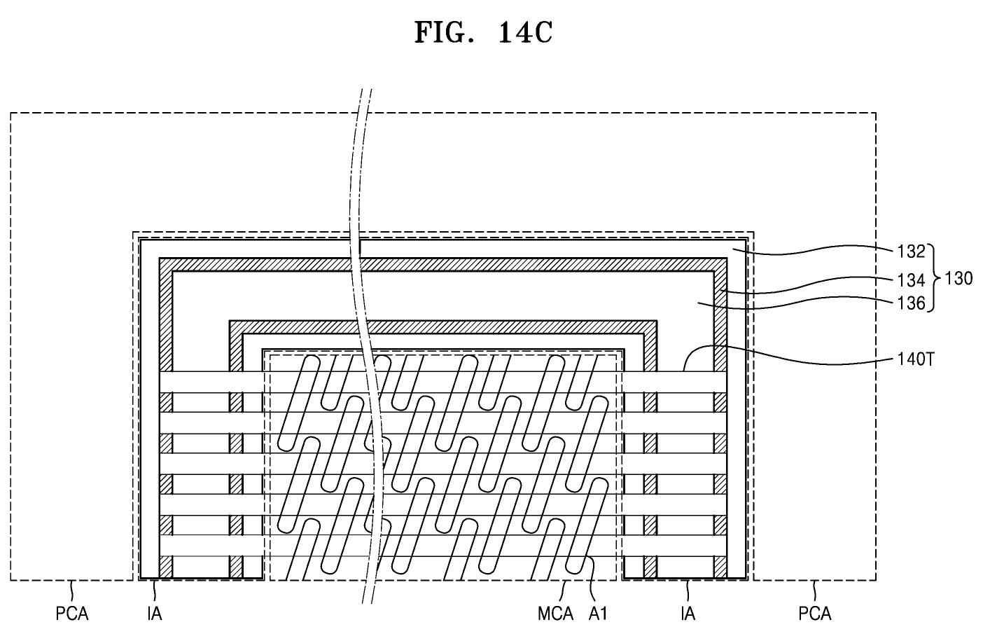

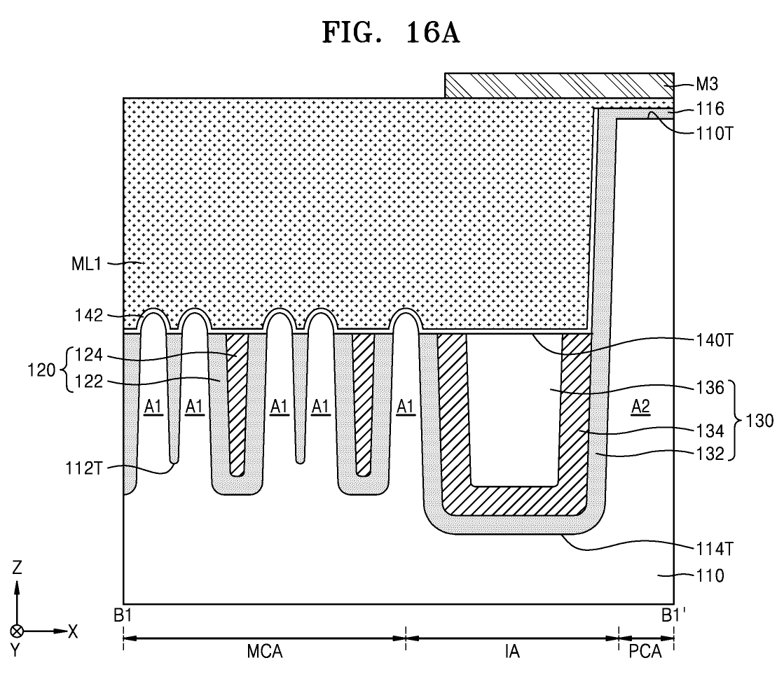

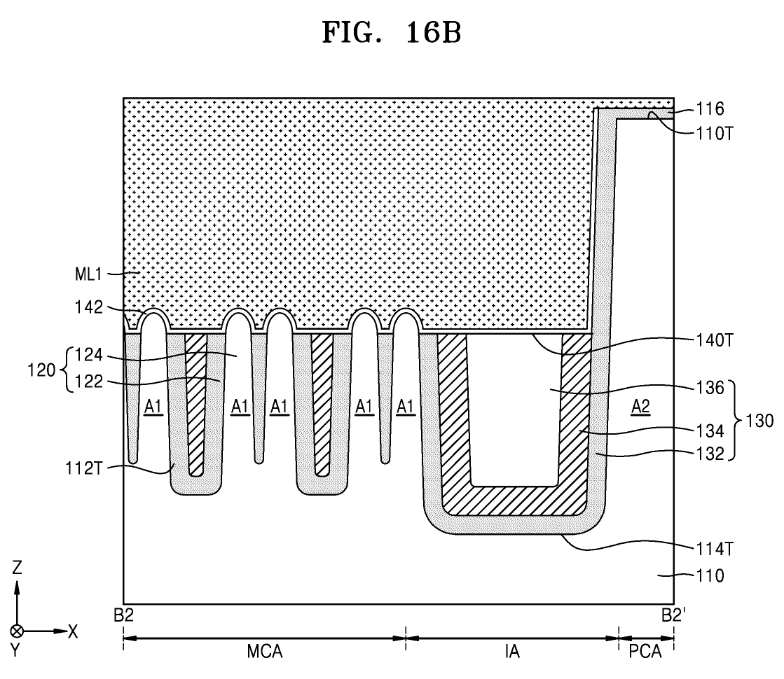

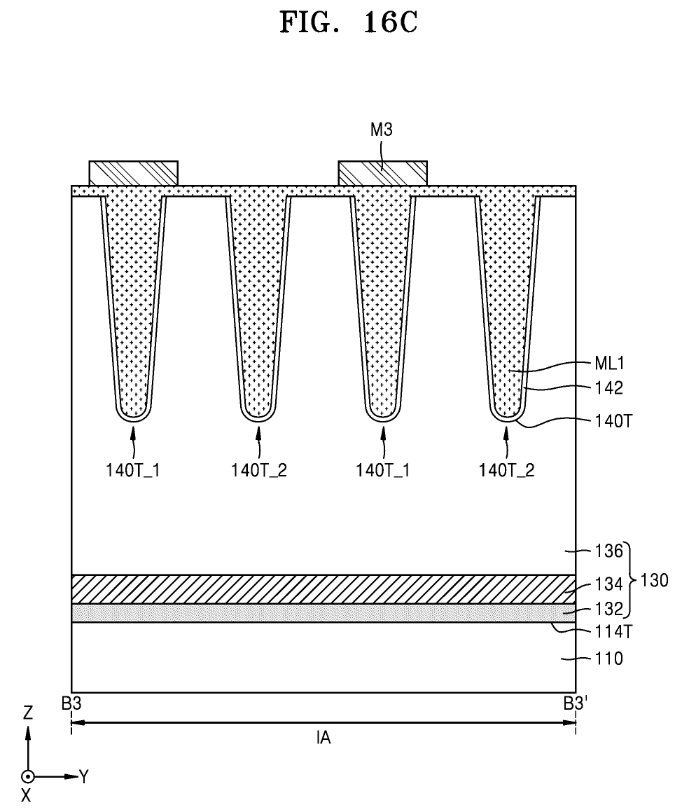

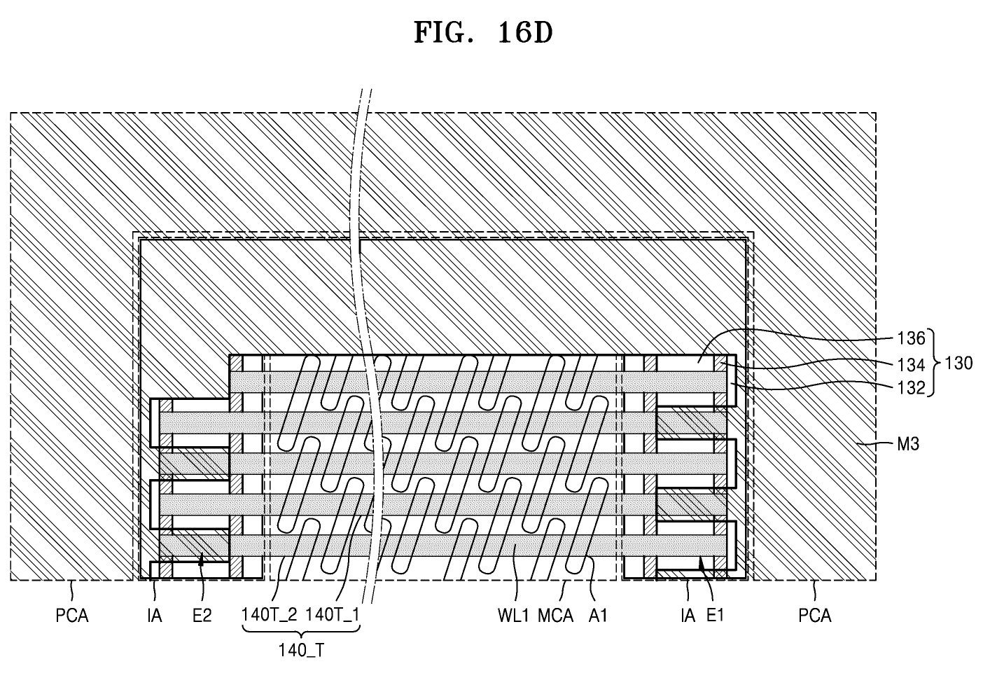

Specifically, FIGS. 11, 12, 13A, 14A, 15, 16A, 17A, 18A, 19A, and 20A are cross-sectional views corresponding to the line B1-B1' of FIG. 2. FIGS. 16B, 17B, 18B, 19B, and 20B are cross-sectional views corresponding to the line B2-B2' of FIG. 2, FIGS. 14B, 16C, 17C, 18C, 19C, and 20C are cross-sectional views corresponding to the line B3-B3' of FIG. 2, and FIGS. 13B, 14C, and 16D are plan views corresponding to operations illustrated in FIGS. 13A, 14A, and 16A.

Referring to FIG. 11, the substrate 110 having the cell array region MCA, the peripheral circuit region PCA, and the interface region IA therebetween may be prepared. According to embodiments, a first mask pattern M1 may be formed on the top surface 110T of the substrate 110 to cover part of the cell array region MCA and part of the peripheral circuit region PCA. Then, the substrate 110 may be etched by using the first mask pattern M1 as an etching mask to form the device isolation trenches 112T in the cell array region MCA and to form the interface trench 114T in the interface region IA.

In embodiments, the plurality of active regions A1 of the substrate 110 may be defined in the cell array region MCA by the device isolation trenches 112T and the interface trench 114T, and the peripheral circuit active region A2 of the substrate 110 may be defined in the peripheral circuit region PCA. Each of the plurality of active regions A1 may have a fin structure FS.

In embodiments, the first mask pattern M1 may include an oxide layer, polysilicon, or a combination thereof. However, the inventive concept is not limited thereto.

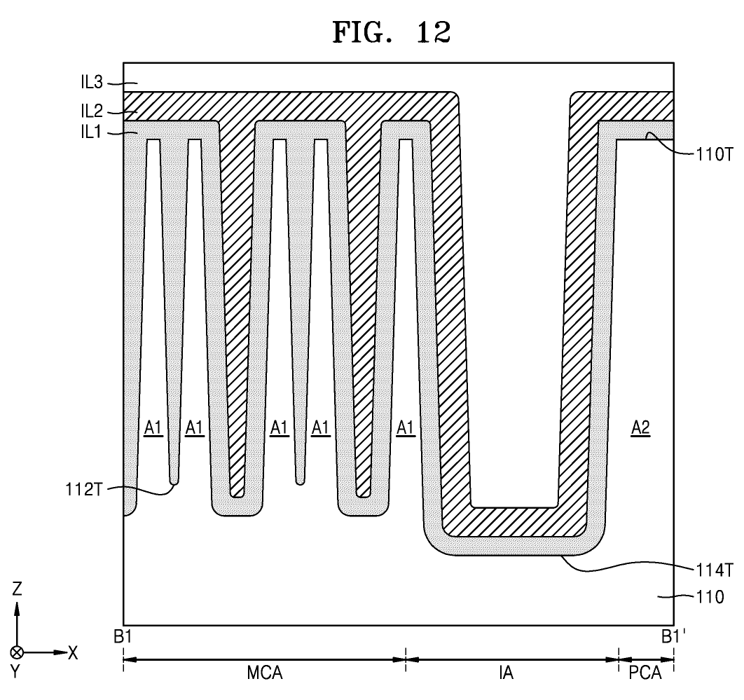

Referring to FIG. 12, after removing the first mask pattern M1 from the result of FIG. 11, a first insulating layer IL1, a second insulating layer IL2, and a third insulating layer IL3 may be sequentially formed on the substrate 110.

In embodiments, in the device isolation trench 112T, some regions may be filled with only the first insulating layer IL1 according to a horizontal width, and other regions may be filled with the first insulating layer IL1 and the second insulating layer IL2. In the interface trench 114T, the first insulating layer IL1 may be formed to cover the bottom surface and the internal wall of the interface trench 114T, the second insulating layer IL2 may be formed on the first insulating layer IL1 to fill part of the interface trench 114T, and the third insulating layer IL3 may fill a space limited by the second insulating layer IL2.

In embodiments, each of the first insulating layer IL1, the second insulating layer IL2, and the third insulating layer IL3 may be formed by chemical vapor deposition (CVD) and/or ALD.

Referring to FIGS. 13A and 13B, the first insulating layer IL1, the second insulating layer IL2, and the third insulating layer IL3 on the top surface 110T of the substrate 110 may be partially removed from the result of FIG. 12 by an etching process to form the device isolation structure 120 and the insulating boundary structure 130.

In embodiments, the insulating thin film 116 that is part of the insulating layers formed to cover the top surface 110T of the substrate 110 to form the device isolation structure 120 and the insulating boundary structure 130 may remain covering the top surface 110T of the substrate 110. For example, the insulating thin film 116 may protect a surface of the substrate 110 in an ion implantation process for implanting impurity ions into the substrate 110 in a subsequent process or in a subsequent etching process.

Referring to FIGS. 14A to 14C, in the result of FIGS. 13A and 13B, a second mask pattern M2 may be formed on the substrate 110, the device isolation structure 120, and the insulating boundary structure 130 to expose part of the cell array region MCA and part of the interface region IA. In some embodiments, a plurality of word line trenches 140T may be formed by etching part of the plurality of active regions A1, part of the device isolation structure 120, and part of the insulating boundary structure 130 by using the second mask pattern M2 as an etching mask.

In embodiments, the second mask pattern M2 may include an oxide layer, an amorphous carbon layer (ACL), an SiON layer, or a combination thereof. However, the inventive concept is not limited thereto.

In embodiments, the word line trench 140T may include a first bottom surface 140TB1 exposing the device isolation structure 120 and a second bottom surface 140TB2 exposing the saddle fin portion of the plurality of active regions A1. Due to a difference in etch rate between the substrate 110 and the device isolation structure 120, the second bottom surface 140TB2 may be at a higher vertical level than the first bottom surface 140TB1, and the bottom surface of the word line trench 140T may have a concavo-convex structure.

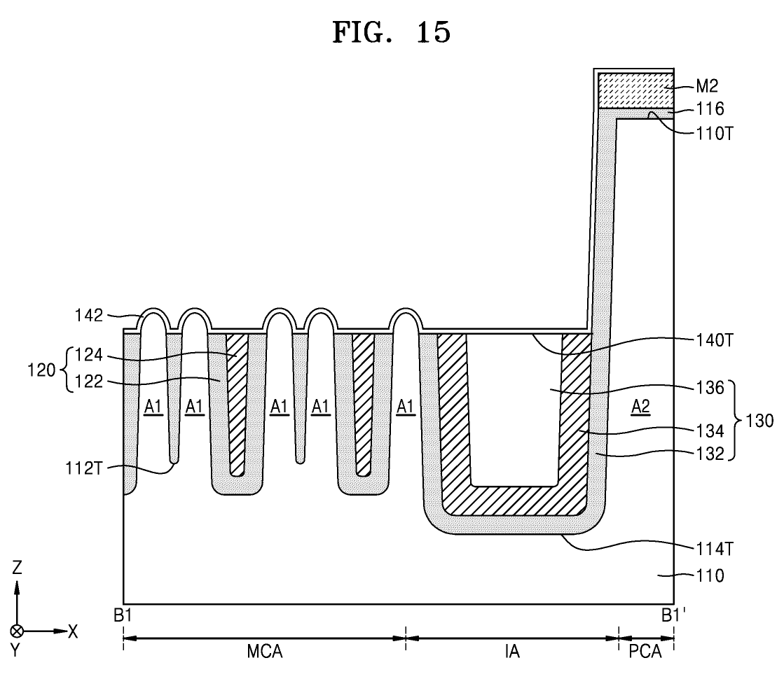

Referring to FIG. 15, the gate dielectric layer 142 may be formed to cover the internal wall and the bottom surface of the word line trench 140T in the result of FIGS. 14A to 14C. In some embodiments, the gate dielectric layer 142 may be formed by an ALD process.

Referring to FIGS. 16A-16D, after removing the second mask pattern M2 from the result of FIG. 15, the first metal layer ML1 may be formed to fill the word line trench 140T. In some embodiments, the first metal layer ML1 may cover a top surface of the insulating thin film 116.

Thereafter, a third mask pattern M3 may be formed in the peripheral circuit region PCA and the interface region IA to cover the first metal layer ML1 and to expose the cell array region MCA. A constituent material of the third mask pattern M3 is the same as described above for the second mask pattern M2.

In embodiments, the third mask pattern M3 may have a wave pattern shape or a staggered pattern shape including a plurality of protrusions in the interface region IA. In embodiments, as illustrated in FIG. 16D, the third mask pattern M3 may include part having a square wave pattern shape in the interface region IA.

In embodiments, the word line trench 140T may include a first word line trench 140T_1 and a second word line trench 140T_2 that are alternately arranged. The third mask pattern M3 may cover a first end E1 of the first word line trench 140T_1 and may not cover a first end E1 of the second word line trench 140T_2. In addition, the third mask pattern M3 may not cover a second end E2 of the first word line trench 140T_1 and may cover a first end E1 of the second word line trench 140T_2.

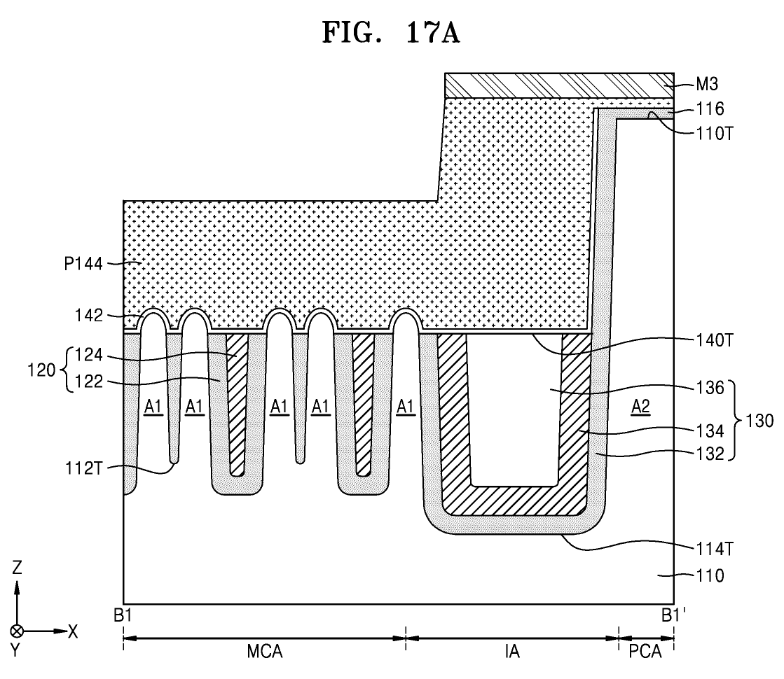

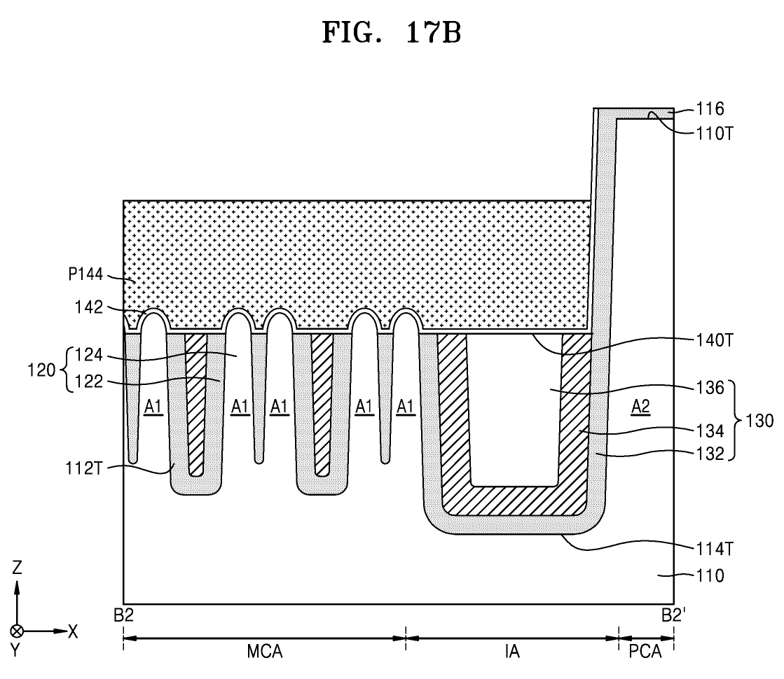

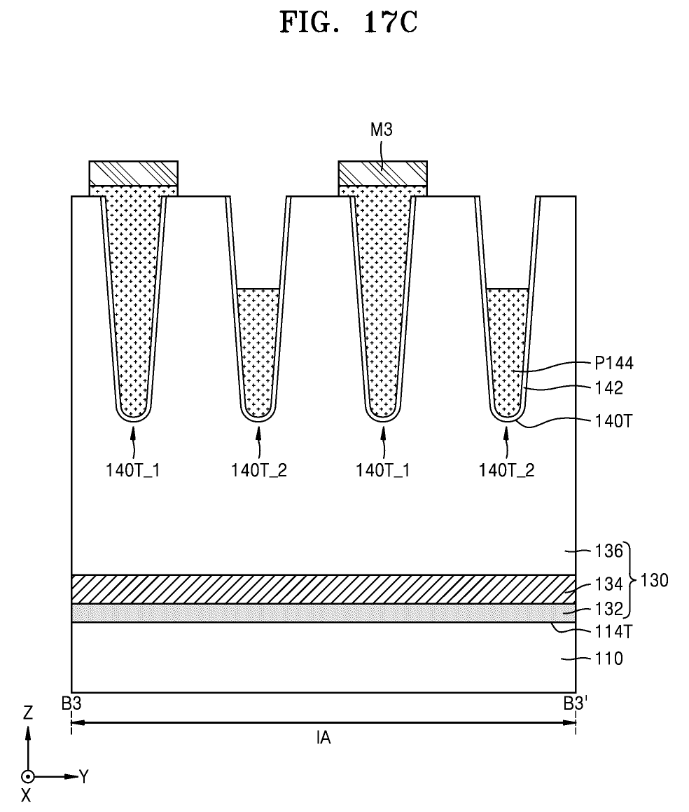

Referring to FIGS. 17A to 17C, part of the first metal layer ML1 may be removed from the result of FIGS. 16A to 16D by using the third mask pattern M3 as an etching mask to form a preliminary conductive line P144. Top surfaces of portions of the preliminary conductive line P144 not covered with the third mask pattern M3 may be lowered to be at a lower vertical level than the top surface 110T of the substrate 110. For example, the preliminary conductive line P144 arranged in the first word line trench 140T_1 may have a step structure at the first end E1, and the preliminary conductive line P144 arranged in the second word line trench 140T_2 may have a step structure at the second end E2 (refer to FIG. 16D).

In embodiments, as illustrated in FIG. 17C, in which a cross-section at the first end E1 is illustrated by way of example, a top surface of the preliminary conductive line P144 arranged in the first word line trench 140T_1 at the first end E1 may be at a higher vertical level than a top surface of the preliminary conductive line P144 arranged in the second word line trench 140T_2 at the first end E1.

In embodiments, in the gate dielectric layer 142, a portion covering two internal walls of the word line trench 140T facing each other in the second horizontal direction Y may be partially exposed.

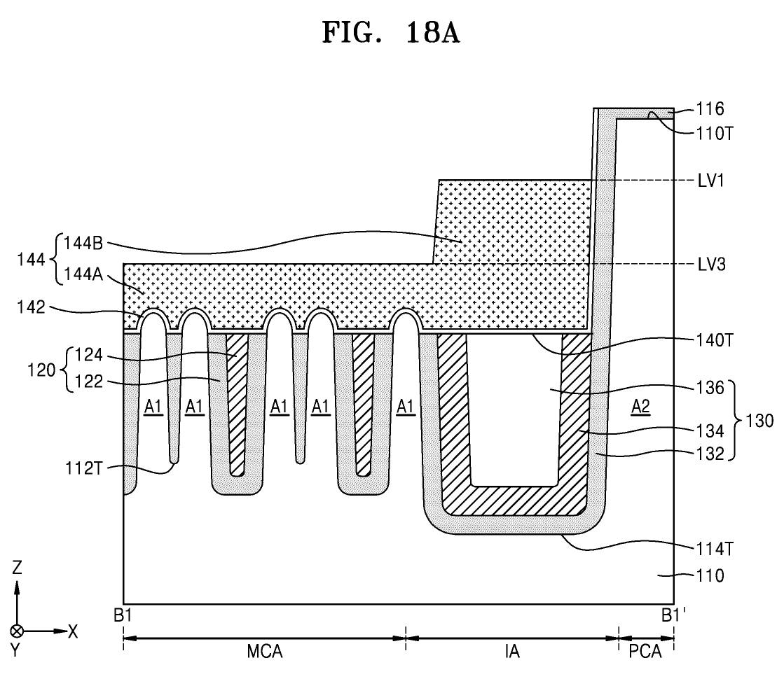

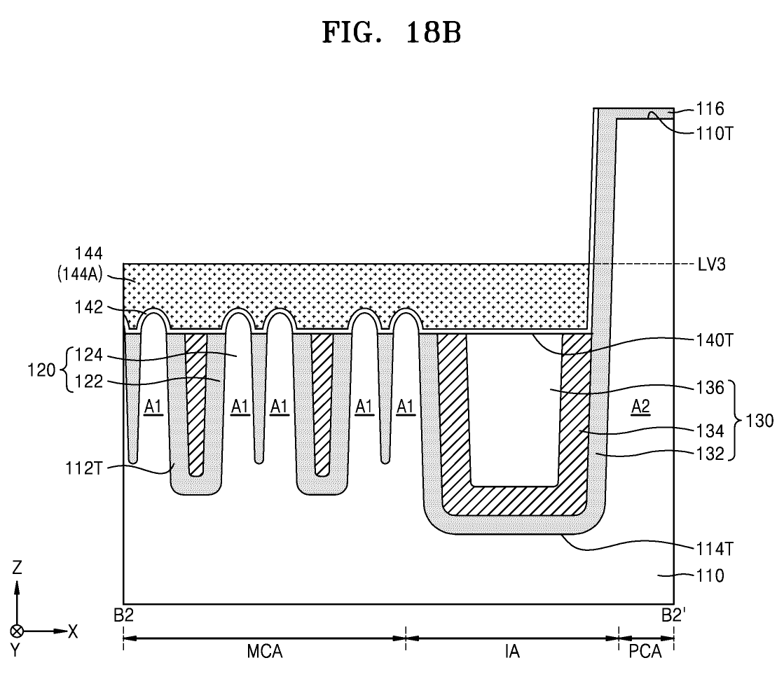

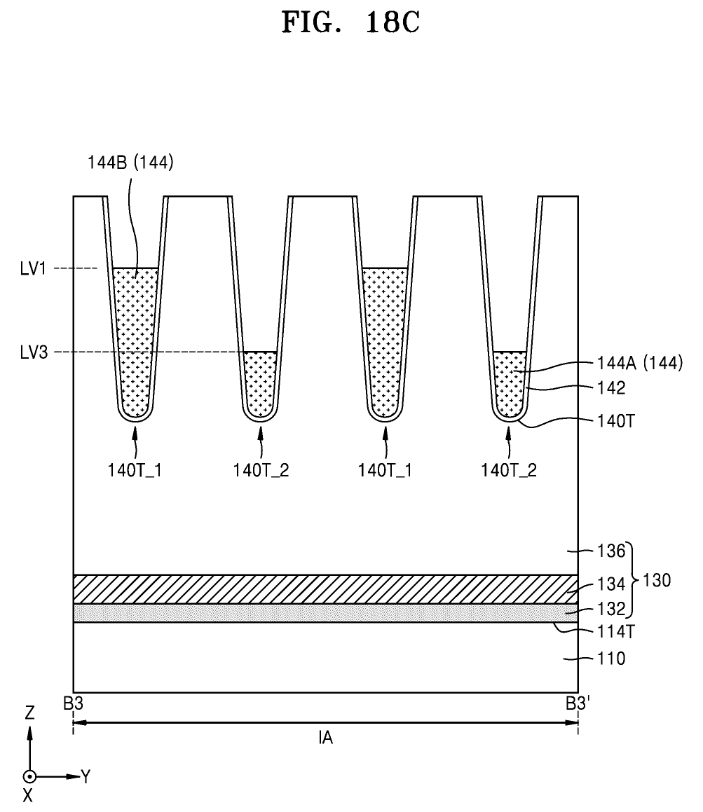

Referring to FIGS. 18A to 18C, after removing the third mask pattern M3 from the result of FIGS. 17A to 17C, part of the preliminary conductive line P144 may be removed by an etch-back process to form the conductive line 144. For example, in the word line trench 140T, a top surface of the conductive line 144 may have a profile similar to that of a top surface of the preliminary conductive line P144.

In embodiments, the conductive line 144 may include the extension 144A and the landing portion 144B, a top surface of the landing portion 144B may be at a first vertical level LV1, and a top surface of the extension 144A may be at a third vertical level LV3.

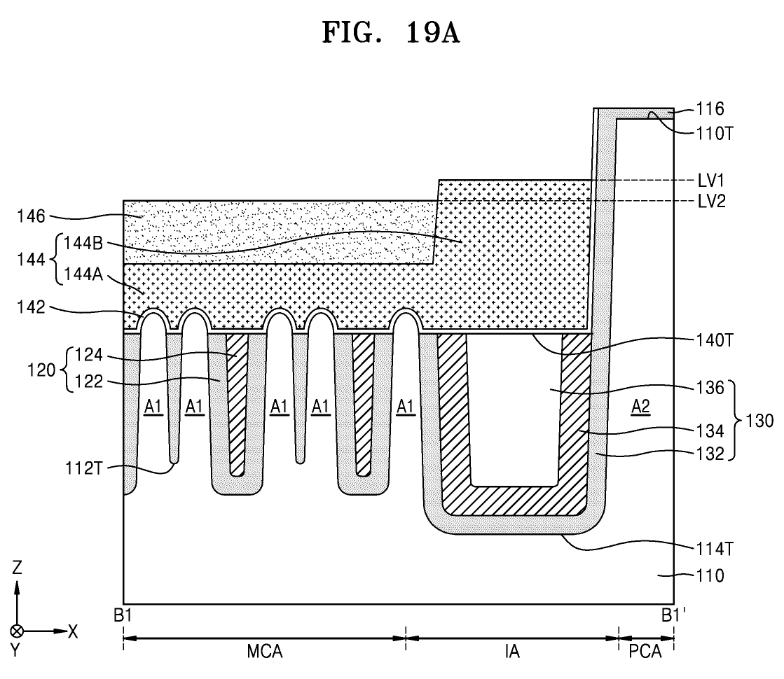

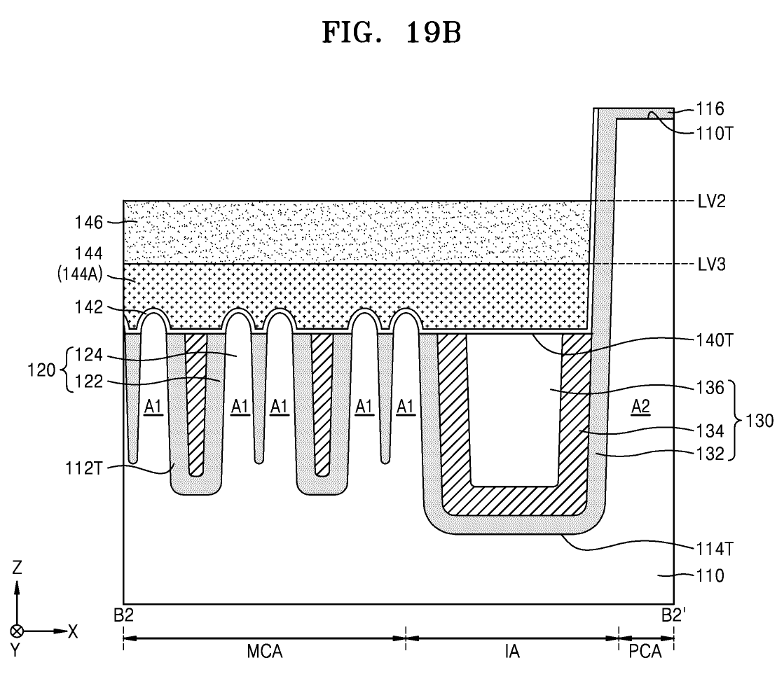

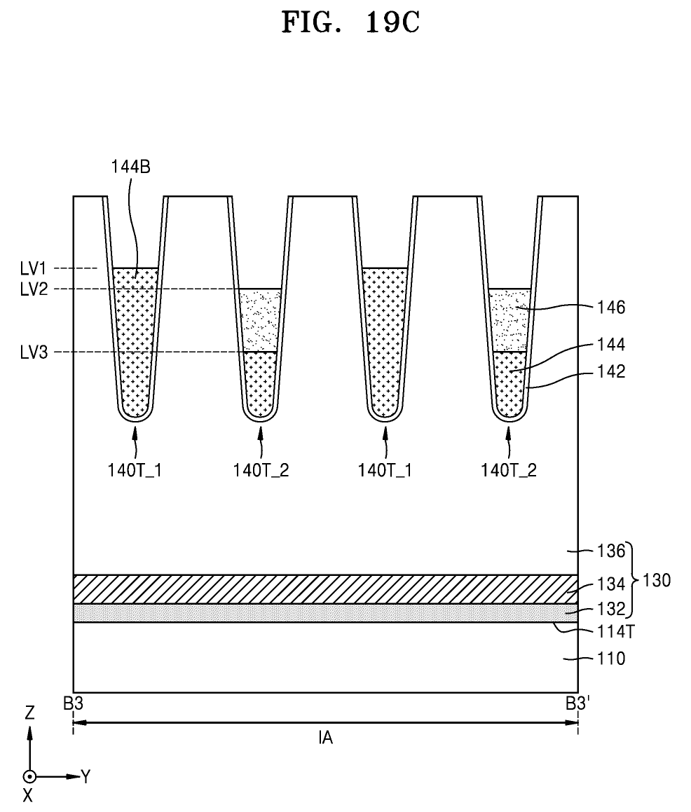

Referring to FIGS. 19A to 19C, after forming a conductive layer filling the word line trench 140T in the result of FIGS. 18A and 18B, part of the conductive layer may be removed through etch-back to form the upper conductive line 146. In embodiments, part of the conductive layer may be further removed after the top surface of the landing portion 144B is exposed in the etch-back process, and thus the top surface of the upper conductive line 146 may be at a second vertical level LV2 lower than a top surface level (for example, the first vertical level LV1) of the landing portion 144B.

In embodiments, the upper conductive line 146 may include polysilicon or doped polysilicon.

In embodiments, as illustrated in FIG. 19C, in which a cross-section at the first end E1 is illustrated by way of example, the landing portion 144B of the conductive line 144 may be arranged in the first word line trench 140T_1 at the first end E1, and the extension 144A of the conductive line 144 and the upper conductive line 146 on the extension 144A may be arranged in the second word line trench 140T_2 at the first end E1. In addition, the top surface of the landing portion 144B arranged in the first word line trench 140T_1 at the first end E1 may be at a vertical level higher than the top surface of the upper conductive line 146 arranged in the second word line trench 140T_2 at the first end E1.

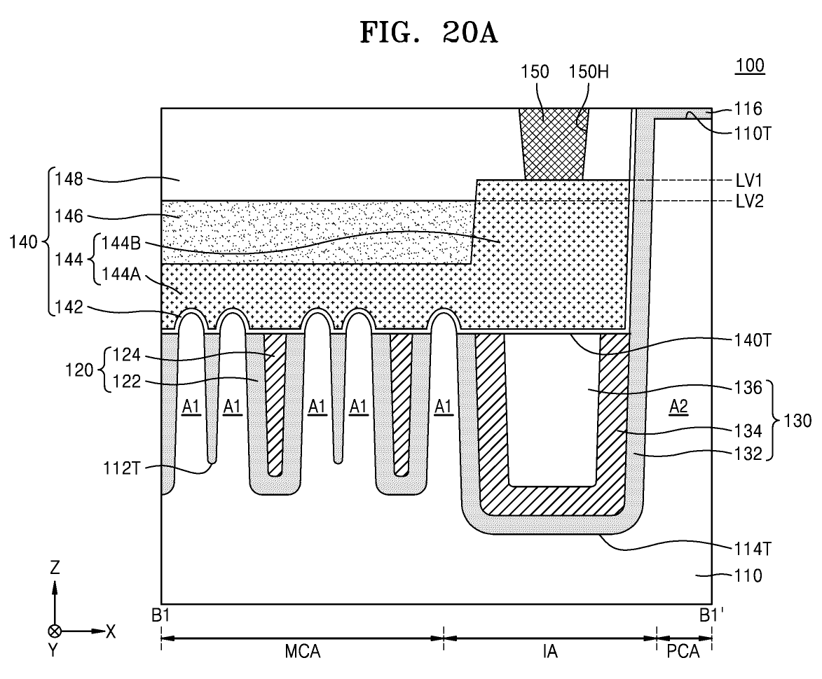

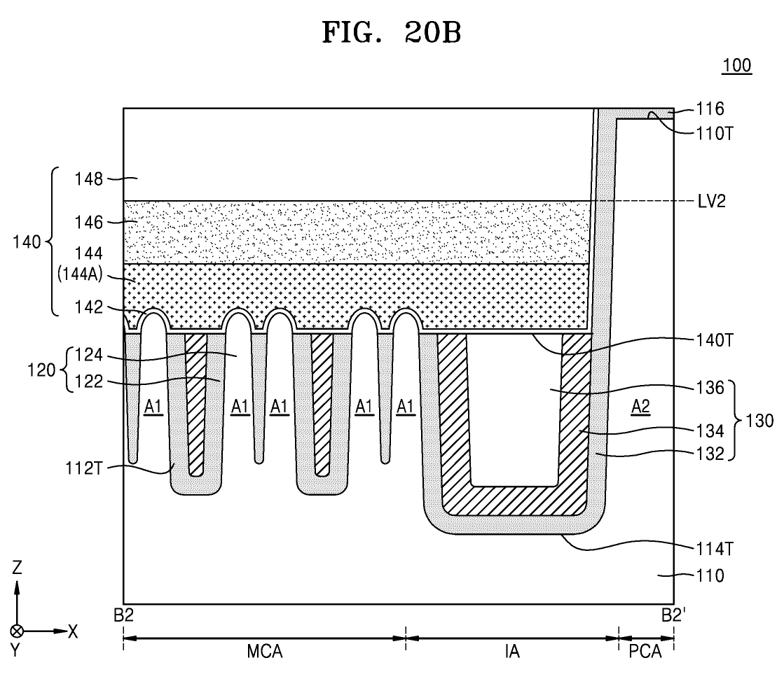

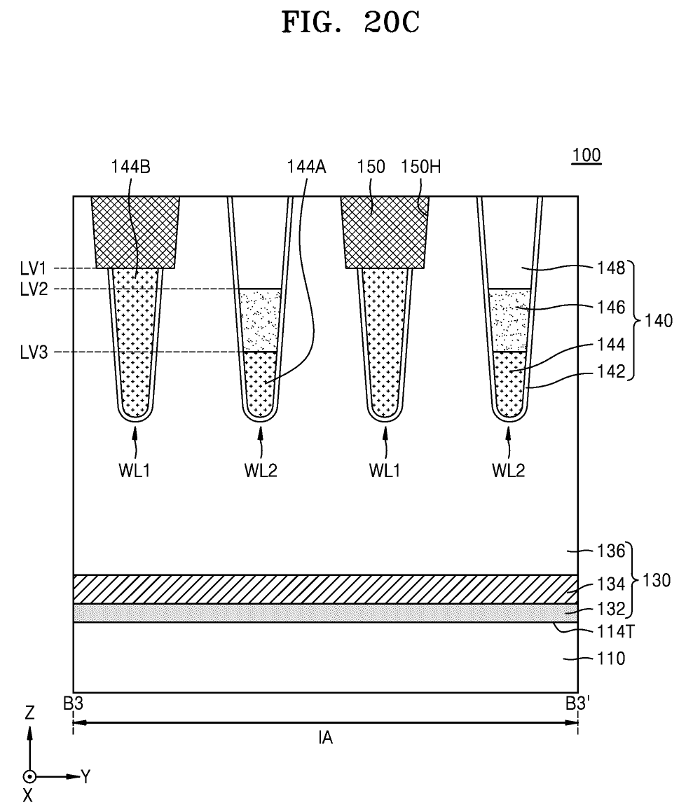

Referring to FIGS. 20A to 20C, the capping layer 148 may be formed to fill the remaining portion of the word line trench 140T in the result of FIGS. 19A to 19C.

Thereafter, the contact hole 150H may be formed to penetrate the capping layer 148 in the vertical direction Z in the interface region IA, and the conductive contact 150 may be formed to fill the contact hole 150H.

In embodiments, the conductive contact 150 may have a width greater than that of the gate structure 140 in the second horizontal direction Y. Both sidewalls of each of the plurality of conductive contacts 150 apart from each other in the second horizontal direction Y may protrude outward with respect to sidewalls of the word line trench 140T.

In embodiments, the bottom surface of the conductive contact 150 may be at a first vertical level LV1. In other embodiments, some of the plurality of conductive contacts 150 may extend into the landing portion 144B, and in this case, the bottom surfaces of the plurality of conductive contacts 150 may be at a vertical level lower than the first vertical level LV1 and higher than the second vertical level LV2.

In embodiments, as illustrated in FIG. 20C, in which a cross-section at the first end E1 is illustrated by way of example, as the landing portion 144B of the conductive line 144 is arranged in the first word line trench 140T_1 at the first end E1, and the upper conductive line 146 is arranged in the second word line trench 140T_2 at the first end E1, although the mask pattern is misaligned in the process of forming the conductive contact 150 on the landing portion 144B, a sufficient distance (a distance in the horizontal or vertical direction) from the upper conductive line 146 in the adjacent second word line trench 140T_2 may be secured. Therefore, occurrence of a bridging defect that refers to the conductive contact 150 on one word line WL being unintentionally electrically connected to an adjacent word line WL may be prevented.

In some embodiments, a process for forming the upper conductive line 146 may be omitted. In this case, the semiconductor device 100A described with reference to FIGS. 7 to 10 may be manufactured.

According to the inventive concept, the landing portion may be formed on the first end of the first word line and the second end of the second word line. Therefore, although the mask pattern is misaligned in the process of forming the word line contact with a relatively large width on the first word line, a sufficient distance from the adjacent second word line may be secured so that occurrence of a bridging defect of the word line contact may be prevented.

While the inventive concept has been particularly shown and described with reference to embodiments thereof, it will be understood that various changes in form and details may be made therein without departing from the spirit and scope of the following claims.

What is claimed is:

1. A semiconductor device comprising:
a substrate including a plurality of active regions; and
a plurality of word lines arranged in a plurality of word line trenches extending in a first horizontal direction in the substrate and arranged to intersect the plurality of active regions,
wherein each of the plurality of word lines comprises a main portion extending in the first horizontal direction and a first end and a second end arranged at both sides of the main portion,
wherein a first word line among the plurality of word lines comprises a first conductive line, and a top surface of the first conductive line is at a first vertical level at the first end, and
wherein a second word line arranged adjacent to the first word line among the plurality of word lines comprises a second conductive line, and a top surface of the second conductive line at the first end is at a second vertical level lower than the first vertical level.

2. The semiconductor device of claim 1,
wherein the first conductive line comprises:
an extension included in a main portion and the second end of the first word line; and
a landing portion included in the first end of the first word line and integrally connected to the extension, and
wherein a top surface of the landing portion of the first conductive line is at a vertical level higher than a top surface of the extension of the first conductive line.

3. The semiconductor device of claim 2,
wherein the second conductive line comprises:
an extension included in a main portion and the first end of the second word line; and
a landing portion included in the second end of the second word line and integrally connected to the extension of the second conductive line, and
wherein a top surface of the landing portion of the second conductive line is at a vertical level higher than a top surface of the extension of the second conductive line.

4. The semiconductor device of claim 3, further comprising:
a first word line contact arranged on the first end of the first word line; and
a second word line contact arranged on the second end of the second word line.

5. The semiconductor device of claim 4, wherein the first word line contact is in contact with the top surface of the landing portion of the first conductive line.

6. The semiconductor device of claim 4, wherein a bottom surface of the first word line contact is at a vertical level higher than the top surface of the second conductive line at the first end.

7. The semiconductor device of claim 4, wherein a bottom surface of the first word line contact is at a vertical level higher than the top surface of the extension of the second conductive line.

8. The semiconductor device of claim 1,
wherein the first word line further comprises:
a first upper conductive line arranged on a top surface of the first conductive line; and
a first capping layer arranged on the first upper conductive line, and
wherein the second word line further comprises:
a second upper conductive line arranged on a top surface of the second conductive line; and
a second capping layer arranged on the second upper conductive line.

9. The semiconductor device of claim 8,
wherein the first conductive line comprises:
an extension included in a main portion and the second end of the first word line; and
a landing portion included in the first end of the first word line and having a top surface at a vertical level higher than the extension of the first conductive line, and
wherein the first upper conductive line is arranged on the extension of the first conductive line.

10. The semiconductor device of claim 9,
wherein the second conductive line comprises:
an extension included in a main portion and the first end of the second word line; and
a landing portion included in the second end of the second word line and having a top surface at a vertical level higher than the extension of the second conductive line, and
wherein the second upper conductive line is arranged on the extension of the second conductive line.

11. The semiconductor device of claim 10,
wherein the first word line further comprises:
a first capping layer in contact with a top surface of the extension of the first conductive line, and
wherein the second word line further comprises:
a second capping layer in contact with a top surface of the extension of the second conductive line.

12. A semiconductor device comprising:
a substrate including a cell array region with a plurality of active regions defined, a peripheral circuit region with at least one peripheral circuit active region defined, and an interface region having an interface trench between the cell array region and the peripheral circuit region;
an insulating boundary structure in the interface trench and surrounding the plurality of active regions in a plan view;
a plurality of word lines extending in a first horizontal direction across the plurality of active regions in the cell array region and extending into the insulating boundary structure of the interface region, the plurality of word lines including a main portion vertically overlapping the cell array region, a first end vertically overlapping the interface region arranged on one side of the cell array region, and a second end vertically overlapping the interface region on an opposite side of the first end,
wherein a first word line among the plurality of word lines comprises:
a first conductive line including an extension arranged at the main portion and the second end, and a landing portion arranged at the first end and integrally connected to the extension and having a top surface at a vertical level higher than a top surface of the extension;
a first upper conductive line arranged on the extension; and
a first capping layer arranged on a top surface of the first upper conductive line and a top surface of the landing portion; and
a first word line contact arranged on the landing portion of the first conductive line.

13. The semiconductor device of claim 12,
wherein a top surface of the landing portion of the first conductive line is at a vertical level higher than a top surface of the first upper conductive line, and
wherein a bottom surface of the first word line contact is at a vertical level higher than a top surface of the first upper conductive line.

14. The semiconductor device of claim 12, wherein, among the plurality of word lines, a second word line adjacent to the first word line comprises:
a second conductive line including an extension arranged at the main portion and the first end, and a landing portion arranged at the second end and integrally connected to the extension and having a top surface at a vertical level higher than a top surface of the extension of the second conductive line;
a second upper conductive line arranged on the extension of the second conductive line; and
a second capping layer arranged on a top surface of the second upper conductive line and a top surface of the landing portion of the second conductive line.

15. The semiconductor device of claim 14,
wherein a top surface of the landing portion of the second conductive line is at a vertical level higher than the top surface of the second upper conductive line, and
wherein a bottom surface of the first word line contact is at a vertical level higher than the top surface of the second upper conductive line.

16. The semiconductor device of claim 14, further comprising a second word line contact arranged on the landing portion of the second conductive line.

17. A semiconductor device comprising:
a substrate including a cell array region with a plurality of active regions defined, a peripheral circuit region with at least one peripheral circuit active region defined, and an interface region having an interface trench between the cell array region and the peripheral circuit region;
an insulating boundary structure in the interface trench and surrounding the plurality of active regions in a plan view; and
a plurality of word lines extending in a first horizontal direction across the plurality of active regions in the cell array region and extending into the insulating boundary structure of the interface region, the plurality of word lines including a main portion vertically overlapping the cell array region, a first end vertically overlapping the interface region arranged on one side of the cell array region, and a second end vertically overlapping the interface region on an opposite side of the first end,
wherein a first word line among the plurality of word lines comprises:
a first conductive line including an extension arranged at the main portion and the second end, and a landing portion arranged at the first end and integrally connected to the extension and having a top surface at a vertical level higher than a top surface of the extension of the first conductive line; and
a first upper conductive line arranged on the extension, and
wherein, among the plurality of word lines, a second word line adjacent to the first word line comprises:
a second conductive line including an extension arranged at the main portion and the second end, and a landing portion arranged at the first end and integrally connected to the extension of the second conductive line and having a top surface at a vertical level higher than a top surface of the extension of the second conductive line; and
a second upper conductive line arranged on the extension of the second conductive line.

18. The semiconductor device of claim 17, wherein a top surface of the second upper conductive line is at a vertical level lower than a top surface of the landing portion of the first conductive line.

19. The semiconductor device of claim 17, further comprising:
a first word line contact arranged on the landing portion of the first conductive line; and
a second word line contact arranged on the landing portion of the second conductive line.

20. The semiconductor device of claim 19, wherein a bottom surface of the first word line contact is at a vertical level higher than the top surface of the second conductive line at the first end.
